(19) United States
(12) Patent Application Publication
(10) Pub. No.: US 2019/0363109 A1
(43) Pub. Date: Nov. 28, 2019

(54) ARRAY SUBSTRATE, PREPARATION METHOD THEREOF, AND DISPLAY DEVICE

(71) Applicant: Wuhan China Star Optoelectronics Technology Co., Ltd., Wuhan (CN)

(72) Inventor: Kun Yang, Shenzhen (CN)

(21) Appl. No.: 16/198,809

(22) Filed: Nov. 22, 2018

Related U.S. Application Data
(63) Continuation of application No. PCT/CN2018/107452, filed on Sep. 26, 2018.

(30) Foreign Application Priority Data
May 28, 2018 (CN) 201810524721.0

(51) Int. Cl. H01L 27/12; G06F 3/044; G06F 3/041

(52) U.S. Cl. CPC H01L 27/1248; H01L 27/1262; G06F 2203/04103; G06F 3/0412; G06F 3/044

(57) ABSTRACT

An array substrate, a preparation method thereof, and a display device are described. The array substrate includes a base substrate; a multi-layer film structure formed on the base substrate, and a layer of touch signal line formed on the multi-layer film structure. The multi-layer film structure has at least an interlayer insulating layer, and the interlayer insulating layer is provided with openings for releasing stress between the film layers. The stress in respective film layers of the array substrate can be released by using the feature of the present application, and the fracture problem of film layers covered by the sealant during the cutting process is prevented.

### CROSS-REFERENCE TO RELATED APPLICATIONS

The present disclosure is a continuation-application of International (PCT) Patent Application No. PCT/CN2018/107452, filed on Sep. 26, 2018, which claims foreign priority of Chinese Patent Application No. 201810524721.0, filed on May 28, 2018 in the State Intellectual Property Office of China, the entire contents of which are hereby incorporated by reference.

### TECHNICAL FIELD

The present application relates to the field of display technologies, and in particular, to a color film substrate, a preparation method thereof, and a display device.

### BACKGROUND

The touch panel (TP) trace of a high pixel density in-cell touch panel, such as PPI (Pixels Per Inch) is generally designed with a separate layer to realize the transmission of TP signals. As the panel design is progressing toward ultra-narrow bezel, the requirements for the sealant width and cell cutting of which are getting higher.

In the fabrication process of an array substrate, the “tension stress” or “pull stress” is occurred in different deposition methods for different films. Take an insulating layer for example, that silicon nitride (SiNx) or silicon oxide (SiOx) is generally applied. The silicon film layer herein generally exhibits “pull stress”, while the silicon oxide film layer generally exhibits “tension stress”. The combination of different film layer tends to cause uneven stress between these film layers in the array substrate.

Due to the problem of uneven stress within the film layers of the array substrate, the stress unevenness of the array substrate is easily aggravated during the sealant curing process when forming it into a cell. And, in the cut on seal process of the narrow bezel, the film layers covered by the sealant are easily to be fractured during cutting. The fracture of the film layers on the edge of sealant of the panel terminal is likely to cause breakage of the touch trace, resulting in failure of the touch function.

### SUMMARY

The present application provides an array substrate, a preparation method thereof, and a display device, which can effectively release the stress between film layers of the array substrate, and prevent the film layers covered by the sealant from being fractured during the cutting process.

In order to solve the above technical problem, a technical solution adopted by the present application is to provide a display device. The display device may comprise an array substrate, which comprising: a base substrate; a multi-layer film structure, formed on the base substrate; and a layer of touch signal line, formed on the multi-layer film structure. The multi-layer film structure may comprise at least an interlayer insulating layer, and the interlayer insulating layer may be provided with openings for releasing stress between the film layers, wherein the openings may be filled with a metal material, and cross-sectional areas of the openings may be at least one of a square shape, a circular shape, an elliptical shape, and a polygonal shape.

In order to solve the above technical problem, another technical solution adopted by the present application may be to provide an array substrate. The array substrate may comprise: a base substrate; a multi-layer film structure, formed on the substrate; and a layer of touch signal, formed on the multi-layer film structure. The multi-layer film structure may comprise at least an interlayer insulating layer, the interlayer insulating layer may be provided with openings for releasing stress between the film layers.

In order to solve the above technical problem, yet another technical solution adopted by the present application may be to provide a preparation method of an array substrate. The preparation method may comprise: preparing a multi-layer film structure on a base substrate; and forming a layer of touch signal line on the multi-layer film structure. Wherein, the multi-layer film structure may comprise at least an interlayer insulating layer, and the interlayer insulating layer may be provided with openings for releasing stress between the film layers.

The beneficial effects of the present application are: providing an array substrate, a preparation method thereof, and a display device. By providing openings on the interlayer insulating layer, the stress between the film layers of the array substrate can be effectively released, and during the cutting process, the fracture problem of the film layers covered by the sealant can be prevented.

### BRIEF DESCRIPTION OF THE DRAWINGS

FIG. 1 is a schematic diagram of an array substrate according to a first embodiment of the present application.

FIG. 2 is a schematic diagram showing a first embodiment of openings on an interlayer insulating layer of the present application.

FIG. 3 is a schematic diagram showing a second embodiment of openings on an interlayer insulating layer of the present application.

FIG. 4 is a schematic flow chart of a method for preparing an array substrate according to one embodiment of the present application.

FIG. 5 is a schematic diagram of a display device according to one embodiment the present application.

### DETAILED DESCRIPTION

Below embodiments of the disclosure will be described in detail, examples of which are shown in the accompanying drawings, in which the same or similar reference numerals have been used throughout to denote the same or similar elements or elements serving the same or similar functions. The embodiments described below with reference to the accompanying drawings are exemplary only, meaning they are intended to be illustrative of rather than limiting the disclosure.

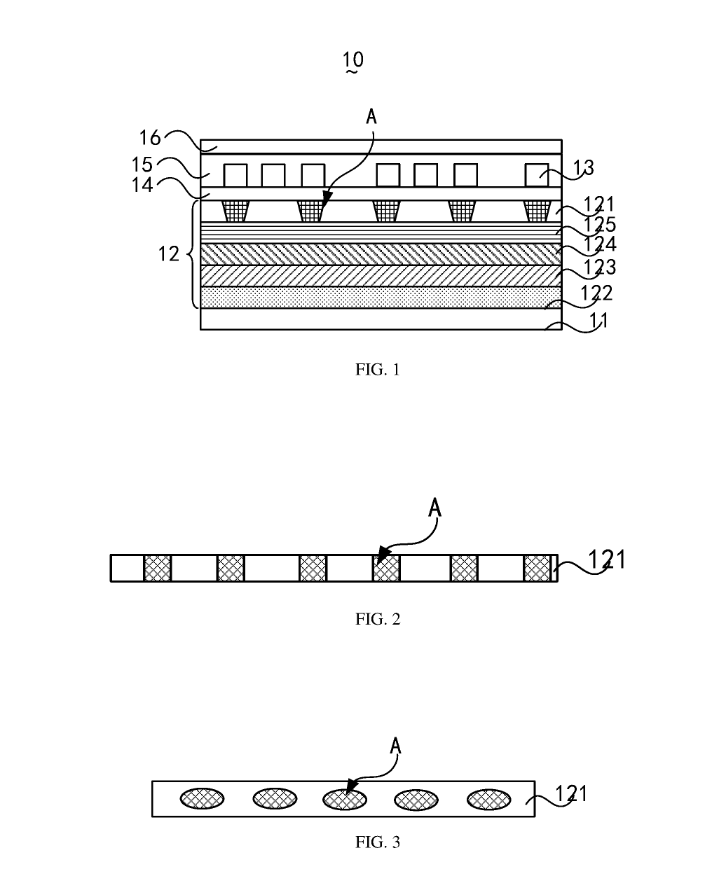

Please refer to FIG. 1, which is a schematic diagram of an array substrate according to a first embodiment of the present application. As shown in FIG. 1, the array substrate 10 provided by the present application may comprise a base substrate 11, a multi-layer film structure 12, and a layer of touch signal line 13.

The base substrate 11 may be a transparent material, and in particular, may be any substrate composed of glass, ceramic, or transparent plastic, which is not limited herein. In this embodiment, the base substrate is a glass substrate.

The multi-layer film structure 12 may be formed on the base substrate 11, and the multi-layer film structure 12 may comprise at least an interlayer insulating layer 121. The material of the interlayer insulating layer 121 can be silicon nitride or silicon oxide. In this embodiment, the interlayer insulating layer 121 may be provided with openings A for releasing stress between the film layers of the array substrate, thereby reducing the fracture possibility of film layers in the subsequent cutting process.

Optionally, the cross-sectional shape of the openings A in this embodiment may be at least one of a square shape, a circular shape, an elliptical shape, and a polygonal shape. In one embodiment, the shape of the openings A can be identical or different. The cross-sectional areas of the openings A at different positions may be different. As shown in FIG. 1, the cross-sectional area may gradually increase or decrease from the bottom of the opening toward the top, or may remain unchanged as shown in FIG. 2. Of course, in other embodiments, the openings A may also be arranged on the side of the interlayer insulating layer 121 as shown in FIG. 3, the shape of which may be at least one of a square shape, a circular shape, an elliptical shape, and a polygonal shape. Preferably, the specific shape of the openings is not limited herein, as long as it is capable of releasing, eliminating or weakening the stress between the film layers of the array substrate 10. In the present application, by providing the openings A on the interlayer insulating layer 121, it is not necessary to provide other organic films on the interlayer insulating layer 121 to absorb the stress in respective film layers, thereby saving the manufacturing processes.

Optionally, please further refer to FIG. 1, the openings A are filled with a metal material, wherein the metal material may be at least one or a combination of copper, aluminum and titanium. Specifically, the openings A in the present embodiment may be filled with a titanium-aluminum-titanium multilayered metal material. Of course, in other embodiments, the filling material of the openings A can be copper as well. The main purpose is to prevent the film layers covered by the sealant from being fractured in the subsequent processes when forming into the cell, that is, the cutting process. The fracture of the film layers on the edge of sealant of the panel terminal is likely to cause damage of the touch function, and the metal filling material is able to support the entire substrate and also buffer the stress thereon.

Optionally, in the embodiment, by providing the openings A on the interlayer insulating layer, the stress in respective film layers of the array substrate can be effectively released. And, filling the metal material in the openings A can effectively prevent the fracture problem of the film layers covered by the sealant during cutting process, therefore to support the entire substrate and buffer stress thereon.

Please further refer to FIG. 1, the multi-layer film structure 12 of the array substrate 10 in the present application further may comprise a barrier layer 122, a buffer layer 123, an active layer 124, and a gate insulating layer 125 sequentially formed on the base substrate 11. Wherein, the material used for the barrier layer 122 and the buffer layer 123 may be at least one of silicon nitride and silicon dioxide. Of course, other materials can also be used, it is not specifically limited herein.

Optionally, the array substrate 10 further may comprise a planarization layer 14 formed between the interlayer insulating layer 121 and the layer of touch signal line 13, along with a first insulating layer 15 and a plastic frame 16 formed on the layer of touch signal line 13. The planarization layer and the first insulating layer 15 may further comprise a dielectric layer and a passivation layer (not shown) there between. The specific materials of the planarization layer 14, the dielectric layer and the passivation layer can refer to the prior art, and the details are not described herein.

In the above embodiment, by providing openings on the interlayer insulating layer and filling the openings A with a metal material, it is capable to effectively release the stress in respective film layers of the array substrate. Thereby, it prevents the film layers covered by the sealant from being fractured during the cutting process, to support and buffer the stress for the entire substrate.

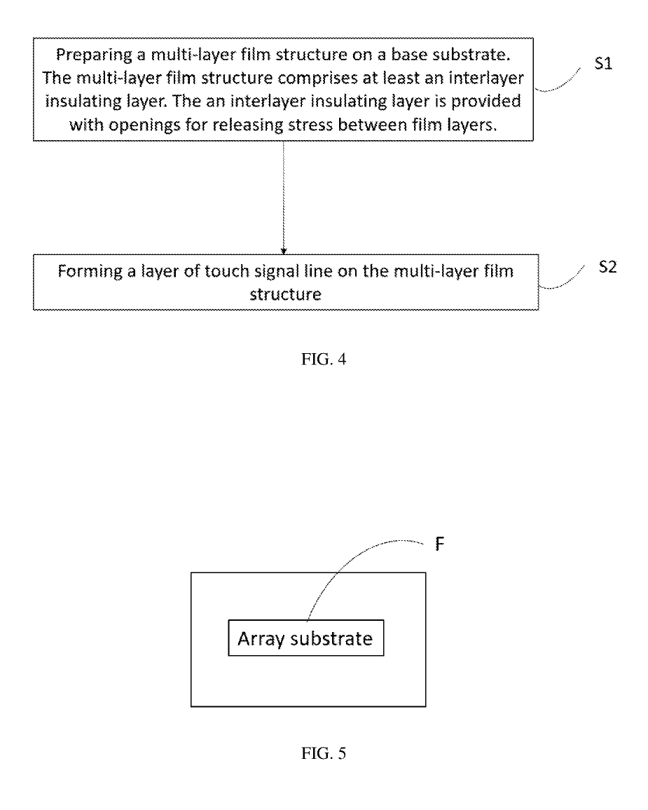

Referring to FIG. 4, it is a schematic flow chart of a method for preparing an array substrate according to one embodiment of the present application. As shown in FIG. 4, the preparing method for the array substrate of the present application, comprises the following steps:

S1, preparing a multi-layer film structure on a base substrate, wherein the multi-layer film structure may comprise at least an interlayer insulating layer, and the interlayer insulating layer may be provided with openings to release stress between the film layers.

Please refer to FIG. 1, the base substrate 11 may be a transparent material, and may be any substrate composed of glass, ceramic, or transparent plastic, which is not limited herein. In this embodiment, the base substrate 11 may be a glass substrate.

Further, when preparing a multi-layer film structure 12 on the base substrate 11,the multi-layer film structure 12 further may comprise a barrier layer 122, a buffer layer 123, an active layer 124, a gate insulating layer 125, and the interlayer insulating layer 121 sequentially formed on the base substrate 11.

The material of the interlayer insulating layer 121 may be silicon nitride or silicon oxide. The interlayer insulating layer 121 may be provided with openings A to release stress in respective film layers of the array substrate 10, thereby reducing the fracture possibility of film layers in the subsequent cutting process. Optionally, the cross-sectional shape of the openings A in the embodiment may be at least one of a square shape, a circular shape, an elliptical shape, and a polygonal shape. In an embodiment, the shape of the openings A can be identical or different. Referring to FIG. 2, the cross-sectional areas of the openings A at different positions may be different, for example, the cross-sectional area may gradually increase or decrease from the bottom of the opening toward the top, or may remain unchanged. Of course, in other embodiments, the openings A may also be arranged on the side of the interlayer insulating layer 121 as shown in FIG. 3, and the shape of which may be at least one of a square shape, a circular shape, an elliptical shape, and a polygonal shape. Preferably, the specific shape of the openings is not limited herein, as long as it is capable of releasing, eliminating or weakening the stress between the film layers of the array substrate 10. In the present application, by providing the openings A on the interlayer insulating layer 121, it is not necessary to provide other organic films on the interlayer insulating layer 121 to absorb the stress between the respective film layers, thereby saving the manufacturing processes.

S2, forming a layer of touch signal line on the multi-layer film structure.

In step S2, the layer of touch signal line 13 may be formed on the multi-layer film structure 12. In this embodiment, after the openings are formed on the interlayer insulating layer 121, it is not necessary to provide other organic films on the interlayer insulating layer 121 to absorb the stress in respective film layers of the array substrate 10, instead the layer of touch signal layer 13 is directly formed on the interlayer insulating layer 121.

Besides, the preparation method further may comprise preparing a planarization layer 14 on the interlayer insulating layer 121, and preparing a first insulating layer 15 and a plastic frame 16 on the layer of touch signal line 13, respectively. The first insulating layer 15 may further comprise a dielectric layer and a passivation layer (not shown). The specific structure and functional principle of the array substrate 10 in this embodiment can refer to the detailed description in the foregoing embodiments, which are not repeated herein.

In the above embodiment, by providing openings in the interlayer insulating layer and filling the openings A with a metal material, it is capable to effectively release the stress between the film layers of the array substrate. Thereby, it prevents the film layers covered by the sealant from being fractured during the cutting process, to support and buffer the stress for the entire substrate.

Please referring to FIG. 5, it is a schematic diagram of a display device according to one embodiment of the present application. The display device in the present application may comprise an array substrate F which is described in any one of the above embodiments. The specific structure and functional principle of the array substrate F in this embodiment can refer to the detailed description in the foregoing embodiments, which are not repeated herein.

In summary, those skilled in the art can easily understand that the present application provides an array substrate, a preparation method thereof, and a display device. By providing openings on the interlayer insulating layer and filling a metal material in the openings, the stress in respective film layers of the array substrate is effectively released. The fracture problem of the film layers covered by the sealant during the cutting process is prevented, and the whole substrate is supported and buffered.

It could be understood that, one skilled in the art may make any equivalence or modification based on the technical solution and the inventive concept of the present disclosure. All these modifications and equivalences shall all be covered within the protection claimed in the claims of the present disclosure.

What is claimed is:

1. A display device having an array substrate, comprising:
a base substrate;
a multi-layer film structure, formed on the base substrate, wherein the multi-layer film structure comprises at least an interlayer insulating layer; the interlayer insulating layer is provided with openings for releasing stress between the film layers; the openings are filled with a metal material, and cross-sectional areas of the openings are at least one of a square shape, a circular shape, an elliptical shape, and a polygonal shape; and
a layer of touch signal line, formed on the multi-layer film structure.

2. The array substrate according to claim 1, wherein the metal material is at least one or a combination of copper, aluminum and titanium.

3. The array substrate according to claim 1, wherein the cross-sectional areas at different locations of the openings are different.

4. The array substrate according to claim 1, wherein the multi-layer film structure further comprises a barrier layer, a buffer layer, an active layer, and a gate insulating layer sequentially formed on the base substrate.

5. The array substrate according to claim 1, wherein the array substrate further comprises a planarization layer formed between the interlayer insulating layer and the layer of touch signal line.

6. The array substrate according to claim 1, wherein the array substrate further comprises a first insulating layer and a plastic frame formed on the layer of touch signal line.

7. An array substrate, comprising:
a base substrate;
a multi-layer film structure, formed on the base substrate, wherein the multi-layer film structure comprises at least an interlayer insulating layer; the interlayer insulating layer is provided with openings for releasing stress between the film layers; and
a layer of touch signal line, formed on the multi-layer film structure.

8. The array substrate according to claim 7, wherein the openings are filled with a metal material.

9. The array substrate according to claim 8, wherein the metal material is at least one or a combination of copper, aluminum and titanium.

10. The array substrate according to claim 7, wherein cross-sectional areas of the openings are at least one of a square shape, a circular shape, an elliptical shape, and a polygonal shape.

11. The array substrate according to claim 10, wherein the cross-sectional areas at different locations of the openings are different.

12. The array substrate according to claim 7, wherein the multi-layer film structure further comprises a barrier layer, a buffer layer, an active layer, and a gate insulating layer sequentially formed on the base substrate.

13. The array substrate according to claim 7, wherein the array substrate further comprises a planarization layer formed between the interlayer insulating layer and the layer of touch signal line.

14. The array substrate according to claim 7, wherein the array substrate further comprises a first insulating layer and a plastic frame formed on the layer of touch signal line.

15. The array substrate according to claim 5, wherein the array substrate further comprises a first insulating layer and a plastic frame formed on the layer of touch signal line.

16. A method for preparing an array substrate, comprising:
preparing a multi-layer film structure on a base substrate, wherein the multi-layer film structure comprises at least an interlayer insulating layer; the interlayer insulating layer is provided with openings to release stress between the film layers; and
forming a layer of touch signal line on the multi-layer film structure.

17. The method for preparing an array substrate according to claim 16, wherein the openings are filled with a metal material.

18. The method for preparing an array substrate according to claim 17, wherein the metal material is at least one or a combination of copper, aluminum and titanium.

19. The method for preparing an array substrate according to claim 16, wherein cross-sectional areas of the openings are at least one of a square shape, a circular shape, an elliptical shape, and a polygonal shape.

20. The method for preparing an array substrate according to claim 19, wherein the cross-sectional areas at different locations of the openings are different.
